(19) United States
(12) Patent Application Publication
(10) Pub. No.: US 2017/0003515 A1
(43) Pub. Date: Jan. 5, 2017

(54) Enhanced Resolution for Images on Microdisplays

(71) Applicant: Dimension Technologies, Inc., Rochester, NY (US)

(72) Inventor: Jesse B. Eichenlaub, Penfield, NY (US)

(21) Appl. No.: 15/200,036

(22) Filed: Jul. 1, 2016

Related U.S. Application Data
(60) Provisional application No. 62/187,325, filed on Jul. 1, 2015.

(51) Int. Cl. G02B 27/58; G02B 3/00; G02B 5/30; G06F 3/01; G02B 27/01; G06T 3/40; G09G 5/391; G02B 27/14; H01S 5/12

(52) U.S. Cl. CPC G02B 27/58; G02B 27/149; G02B 27/141; G02B 27/145; G02B 3/0056; G02B 5/3083; H01S 5/12; G02B 27/0172; G02B 27/0179; G06T 3/4053; G09G 5/391; G06F 3/013; G02B 2027/0147; G09G 2354/00; G09G 2340/0407

(57) ABSTRACT

An enhanced resolution microdisplay system using lenses mounted at a distance from the microdisplay, taking advantage of the Talbot effect, which can be produced using arrays of lenses and mirrors. The Talbot effect image of at least one light source created using a fly's eye lens is imaged onto the microdisplay using a beam splitter, and the combined image is passed by the beam splitter through output optics.

### REFERENCE TO RELATED APPLICATIONS

This application claims one or more inventions which were disclosed in Provisional Application No. 62/187,325, filed Jul. 1, 2015, entitled “Enhanced Resolution for 2D Images on Microdisplays”. The benefit under 35 USC §119(e) of the U.S. provisional application is hereby claimed, and the aforementioned application is hereby incorporated herein by reference.

### BACKGROUND OF THE INVENTION

Field of the Invention

The invention pertains to the field of creation of images using a microdisplay device in such a way that the images have more resolution (i.e. more pixels) than the microdisplay itself.

Description of Related Art

Microdisplays rely on the formation of spots in different sub regions of the pixels of the microdisplay in sequence as the microdisplay pixels rapidly change in gray scale, so that the image formed is made up of the spots instead of the microdisplay pixels. Projection and head mounted systems that rely on this method for the production of high resolution images are described in DTI patents U.S. Pat. No. 6,734,838 and U.S. Pat. No. 7,417,617, both titled “Enhanced Resolution for Image Generation”.

U.S. Pat. No. 6,734,838 relies on lenses embedded in the cover glass of the microdisplay in order to place the lenses close enough to the pixels of the microdisplay to allow spots to be focused on the way out of the lenses in order for the enhanced resolution process to work. This configuration would force microdisplay makers to alter their manufacturing process and components to accommodate the cover glass containing embedded lenses. U.S. Pat. No. 6,734,838 also discloses the use of relay lenses to refocus spots formed near a separated fly's eye lens onto the microdisplay. This configuration is bulky, and requires expensive precision relay lenses.

The embedded lens approach described above has one major drawback—it requires that the microdisplay manufacturer make custom microdisplays containing the embedded lenses, and spend considerable time and money altering their manufacturing process to accommodate the precise alignment required for the lenses. With some microdisplays, embedded lenses cannot be used at all. Most manufacturers have been unwilling to do this. U.S. Pat. No. 7,417,617 further discloses the use of a birefringent lens which can employ polarized illumination in such a way that it focuses light onto spots on the microdisplay but does not affect the light on the way out, thus allowing the observer to see the spots without magnification or other interference by the lenses when the spots are observed through a correctly oriented polarizer. This doubles the distance that the fly's eye lens can be placed in front of the microdisplay, and thus allows it to be placed outside the cover glass in some cases. However, some microdisplays can have such small pixels and/or thick cover glass that this technique cannot be used. In cases where it can be used, the lenses are non-standard and difficult to make.

Periodic lens arrays produce what are known as Talbot Plane images. Talbot Plane images are “copies” of the focal plane images, produced at certain planes beyond the focal plane by the positive interference of the wave fronts emanating from the repeating focal plane images. This effect was described by Besold and Lindlein in an April 1997 article entitled “Fractional Talbert Effect for Periodic Fly's eye lenses,” Optical Engineering, Volume 36, number 4, pg. 1099-1105.

These copies are created at greater distances from the lens than the focal plane, and are formed by the constructive interference of light from many different focal plane images.

Some of these copies will have the same pitch as the original spots as long as collimated light is used to illuminate the lens array.

When monochromatic illumination sources are used, these copy images have much higher angular resolution than the focal plane images because light from a large number of lenslets, covering a relatively large area, goes into the creation of each of the copies. This greater resolution allows small, sharp spot images to be focused at far greater distances from the lens sheet than are possible using focal plane images—far enough away that the lens could potentially be mounted on the far side of a conventional beam splitting cube. Certain of these Talbot Plane images can be made identical in size, pitch, and spot size to the focal plane image. This allows the lens to be completely out of the way of the light exiting the microdisplay, and allows a conventional fly's eye lens to be used with an off the shelf, unmodified microdisplay.

### SUMMARY OF THE INVENTION

The invention allows the use of conventional fly's eye lenses mounted at a distance from the microdisplay without the use of relay optics, even if the microdisplay has very small pixels. This configuration would make use of normal, non-birefringent lenses mounted on the far side of the beam splitting optics that are typically used to view reflective microdisplays. The configuration takes advantage of an optical effect known and the Talbot effect, which can be produced using arrays of lenses.

### BRIEF DESCRIPTION OF THE DRAWING

FIG. 1 shows an illustration of Talbot plane images.

FIG. 2 shows a block diagram of an enhanced resolution display utilizing Talbot plane images of light spots.

FIG. 3 shows an example of an image display at full resolution.

FIG. 4 shows an example of the image of FIG. 3, implementing the area of interest tracking method.

FIG. 5 shows the display of FIG. 2, with additional elements to implement the area of interest tracking system.

FIG. 6 is a flowchart of the area of interest tracking method.

### DETAILED DESCRIPTION OF THE INVENTION

Talbot plane images are illustrated in FIG. 1.

A microlens array 2, such as a fly's eye lens, is illuminated by monochromatic light 1. For purposes of this discussion, the light 1 is assumed to come from laser light sources in the form of collimated beams filling the fly's eye lens 2. The light 1 is focused into images 4 at the common focal plane of the microlenses in the lens array 2, which in the case of collimated laser illumination will be spots of light. The multiple images formed there generate equal or fractional size copies of themselves in the Talbot planes, which are located at greater distances from the fly's eye lens as illustrated in FIG. 1. This effect is produced by positive and negative interference of light waves exiting the images formed by the fly's eye lens 2.

The Talbot plane images shown in FIG. 1 are:
The quarter Talbot plane image 6, which is a quarter size copy of the primary image 4
The half Talbot plane image 8, which is a half-size copy of the primary image 4
A series of “n” full sized images, from the first Talbot plane image 10a through the “nth” Talbot plane image 10n.

Of particular interest are the planes known as the first (or “primary”) Talbot plane 10a and the half Talbot plane 8, as shown in FIG. 1. Within these planes copies of the focal plane images of nearly the same pitch as the original focal plane images are formed (or of the same pitch in the case of collimated illumination at the normal).

The distance between the focal plane 4 of the fly's eye lens 2 and the half 8 or first 10a Talbot planes is linearly dependent on wavelength, so in the example above, the planes associated with red, green, and blue wavelengths will be separated from each other by some distance, typically on the order of several millimeters.

A Talbot plane associated with red light will be closer to the focal plane than the corresponding Talbot plane associated with green light, which in turn will be closer than the corresponding Talbot plane associated with blue light. The distance between the focal plane 4 and the Talbot planes 6, 8 and 10a-10n is also dependent on the pitch of the images in the focal plane 4, and thus will be different for fly's eye lens 2 with differing pitches.

There are three factors which complicate the use of Talbot plane images for this application, and which require variations to the basic design:

1) The distance between the microlens array 2 and the Talbot planes 6, 8 and 10a-10n is proportionately dependent on wavelength. Red, green, and blue light will produce Talbot plane images at distances that are separated by many millimeters from each other.

2) Because of factor 1, above, a microlens array designed to work with Talbot plane images must be illuminated with very narrow band laser light. Lasers are the only common illumination sources that are sufficiently monochromatic and bright enough for the application.

3) Again because of factor 1, above, small changes in laser wavelength with temperature can cause focus distance issues.

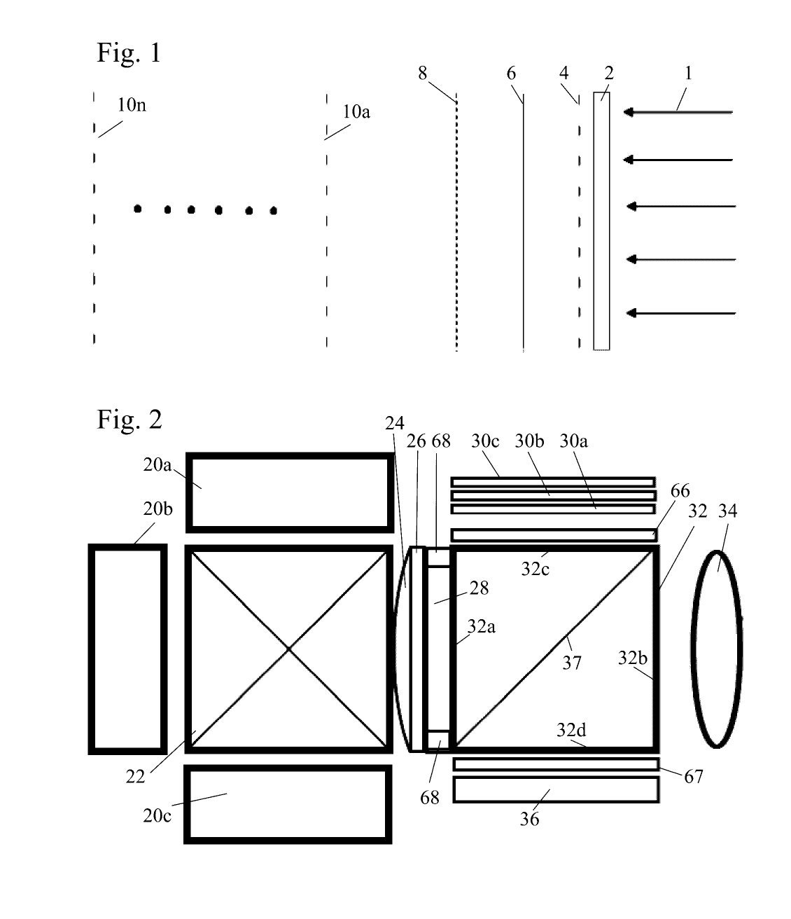

A near-to-eye-resolution microdisplay system using Talbot plane images and which overcomes the disadvantages caused by the three factors listed above is shown in FIG. 2.

Using the system as shown in FIG. 2, the resolution of an image created with a microdisplay device 36 is increased by focusing regions of light, usually in the form of circular spots, formed by a fly's eye lens 28 sequentially into different areas of the pixels of the microdisplay 36, the microdisplay 36 being spaced substantially apart from the fly's eye lens 28. The spots of light originate as an array of images of light sources 20a-20c that are focused by the fly's eye lens 28 in a place close to itself, usually within tens of microns of the lenslets of the fly's eye lens 28. This array of images are reproduced at or very close to the pixel plane of the microdisplay 36 by means of the Talbot effect, which is described above.

The fly's eye lens 28 is a conventional type that when illuminated by monochromatic (laser) light creates an array of very small diffraction-limited spots in a Talbot plane at a large distance (typically 5 mm to 10s of mm) from itself. The distance involved is sufficient to allow such a lens 28 to be mounted on a different side of a beam splitting cube 32 from the microdisplay 36.

Red 20a, green 20b, and blue 20c diode laser illumination is ideally used for this type of lens to work properly, since a very narrow bandwidth is required. In addition, the lasers 20a-20c are preferably of the single mode type and use Bragg reflectors. These types of laser diodes exhibit comparatively little variation in wavelength with temperature.

The red, green, and blue diode laser illumination light sources 20a, 20b, and 20c comes from an array of independently controlled lasers for each color, for example a 2×2 array or a 3×3 array, which collectively constitute the arrays of light sources as described in U.S. Pat. No. 6,734,838 and U.S. Pat. No. 7,417,617.

Light from the three sets of laser diodes (red 20a, green 20b and blue 20c) is flashed in sequence and directed to the fly's eye lens 28 by a beam combiner 22 and, optionally, collimating lens 24. Such beam combiners are readily available off the shelf in the form of dichroic mirror prisms, and are specifically made for the purpose of combining light from red, green and blue light sources into a single beam.

The light from the light sources 20a-20c is linearly polarized either through use of a polarizing filter 26 or through use of light sources (such as lasers) that are linearly polarized to begin with. The original light sources 20a-20c will be large enough that scatter, diffraction, and blockage by the intersection in the beam combiner 22 will not cause any significant effect.

The fly's eye lens 28 forms spot images in its own focal plane, very near to the lens 28, and in Talbot planes at a considerable distance in front of itself. The fly's eye lens 28 is adjacent to a first side of a beam splitter cube 32 which has four sides 32a, 32b, 32c and 32d, and a partially reflective mirror 37. The mirror 37 is oriented at 45° to the sides 32a-32d, so that the mirror 37 passes a portion of light entering the first side 32a through to the second side 32b opposite the first side 32a, and reflects a portion to adjacent third side 32c. Similarly, light entering the beam splitter 32 from the fourth side 32d is partially passed through to third side 32c opposite the fourth side 32d, and a portion is reflected to pass out the second side 32b. Typically, the partially reflective mirror 37 in a beam splitter 32 will be about 50% reflective and 50% transmissive, but other arrangements would be possible.

In particular, mirror 37 will ideally be a polarizing mirror, designed to reflect nearly all linearly polarized light exiting the polarizer 26 and fly's eye lens 28 with a given polarization direction, and to let nearly all linearly polarized light with a perpendicular polarization direction to pass through. Such a mirror will be much more efficient in terms of the use of light than a half reflective mirror, and the following description assumes that a polarizing mirror is present.

Light from the spots in the focal plane is reflected by mirror 37 of the 45 degree beam splitter 32 toward the collection of stacked dichroic mirrors 30a-30c. This light first passes through a ¼ wave retarder 66 placed in front of the stacked dichroic mirrors 30a-30c. The first mirror 30a is dichroic, and reflects red light but lets the other colors through. The second mirror 30b is also dichroic, but reflects green light and lets the remaining blue light through. Blue light passes through the first two mirrors and is reflected by the last mirror 30c. The last mirror 30c can either be dichroic (reflecting blue light) or simply be a highly reflective broadband first surface mirror, such as an aluminized mirror.

Light reflected from the stacked mirrors 30a-30c is reflected back toward microdisplay 36, most of it passing through mirror 37 to microdisplay 36.

Since the three reflective surfaces 30a-30c are in different positions, the travel distance between the fly's eye lens 28 and the microdisplay 36 is different for each color. The thicknesses and positions of the mirrors 30a-30c are chosen so that the travel distance for light of each color is the correct distance to cause its Talbot plane images of all three colors to be focused on the pixels of the microdisplay 36.

On passing out of the mirror system 30a-30c all light goes through ¼ wave retarder 66 again and comes out polarized in the orthogonal direction from which it entered the three-mirror system 30a-30c. It therefore passes through the beam splitter mirror 32 to the microdisplay 36. Depending on what type of microdisplay is used, the microdisplay 36 itself will change the polarization of the light again in the course of forming an image, causing the light that forms the image to reflect off the mirror 37 of the beam splitter 32 again, toward output optics 34, as is known to the art. In the case of a non-polarizing microdisplay, like Texas Instrument's (TI's), a second ¼ wave retarder 67 can be added in front of the microdisplay 36 to cause the polarization direction of the light to change to the orthogonal direction when exiting the microdisplay 36, and thus reflect from the mirror 37 of the beam splitter 32.

An optional component can be used, in the form of thermal expansion blocks 68 at the edges of the fly's eye lens 28. This is a material that expands and contracts with temperature at such a rate that its expansion changes the spacing between the fly's eye lens and mirrors and microdisplay in order to compensate for small changes in laser wavelength with temperature. This component would be an alternative to using lasers with Bragg reflectors.

Although the example above describes a tricolor arrangement, more or fewer colors could be used if an appropriate number of mirrors are provided. For example, four mirrors could be used for a four color system (for example, red, yellow, green, and blue), or two mirrors could be used for a two color system. At the lower limit one fully reflective mirror could be used at a distance in a monochrome system. Note that the mirrors must be in correct order so that shorter wavelength reflecting mirrors are toward the back of the stack. The last mirror can be dichroic or a simple highly reflective broadband first surface mirror.

The diagram in FIG. 2 shows output optics 34 as a viewing lens, but these optics could just as easily be a projection lens designed to project the image of the microdisplay 36 and its spots onto a screen spaced apart at a distance from the optics 34.

Although a reflective microdisplay 36 is described here, the reflective microdisplay 36 could be replaced by a transmissive microdisplay, provided that the output optics 34 (viewing or projection lens) are moved to a position in front of the microdisplay 36, on the side opposite the polarizing beamsplitter 32.

Although a fly's eye lens is described, it is also possible, as is explained in U.S. Pat. No. 6,734,838 and U.S. Pat. No. 7,417,617, to use a lenticular lens if resolution increase in only one direction is desired.

### Incorporating an Area of Interest (AOI) and AOI Tracking Capability

One interesting aspect of this technology is that it can be easily be used to implement an ultra-high resolution area of interest (AOI) display within a lower resolution peripheral field.

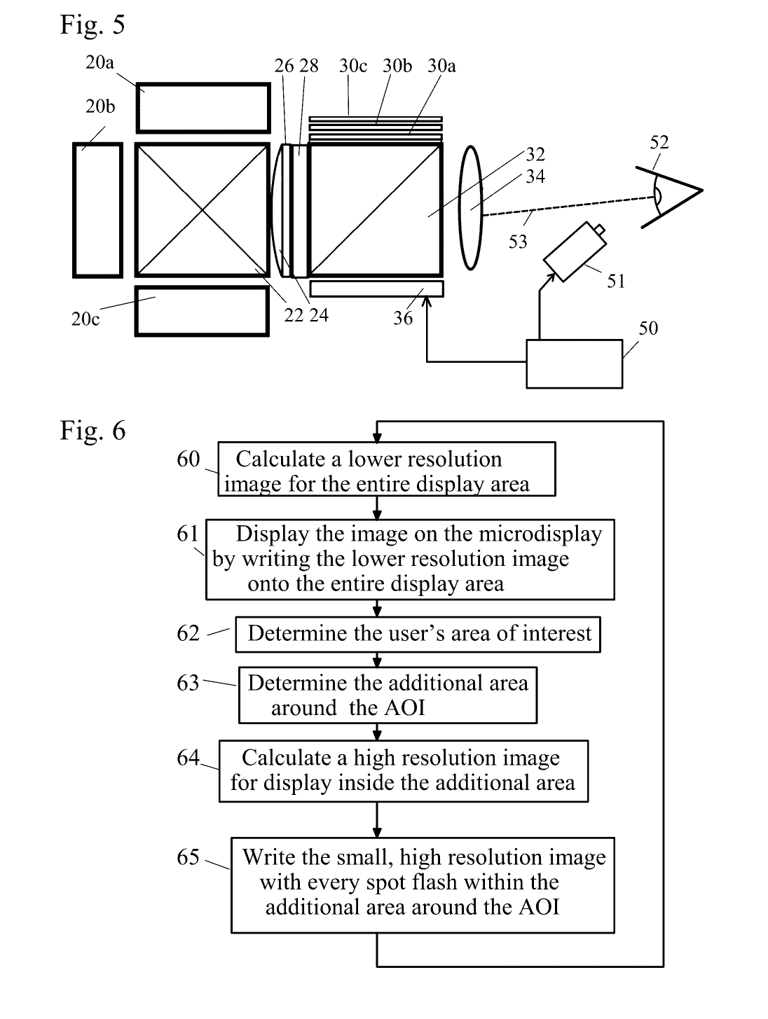

Such a system is shown in block diagram form in FIG. 5. The parts of the display which were previously discussed in respect to FIG. 2, above, bear the same reference numbers in FIG. 5 as in FIG. 2, and the previous discussion is incorporated here by reference.

In FIG. 5 a user 52 is using the display, and is concentrating on one part of the image being displayed on microdisplay 36 by computer 50. This point of focus is called the “gaze point” 53. The computer 50 uses an input from a gaze tracker 51, which monitors the user's 52 eye movements as is known to the prior art, to determine the gaze point 53.

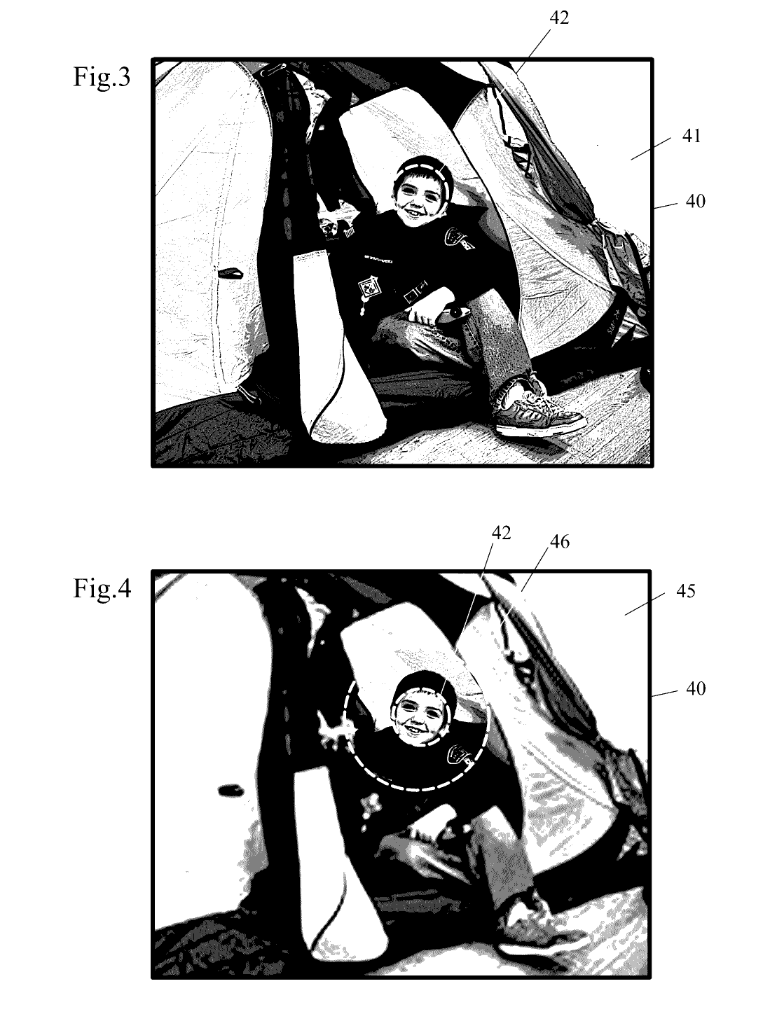

FIGS. 3 and 4 show an example image demonstrating how the AOI method works. FIG. 3 shows an example of an image 41 being displayed on the microdisplay's 36 display area 40. The user's gaze point is centered on an area denoted by circle 42.

Much computational power and/or data throughput could be saved if the computer 50 only had to render the ultra-high resolution images in the small areas surrounding the user's gaze point 53 at any time. FIG. 4 shows the result of this process.

This much smaller area rendered at near maximum resolution only needs to cover the part of the image 42 around the gaze point 53 where the user can see, plus extra area 46 covering the range of rapid saccadic eye movements and extra area beyond that to ensure overlap between one AOI position and the next during rapid longer range eye movements as the user looks at different objects or details in the scene. The rest of the image 45 can be rendered at lower resolution, as is shown in FIG. 4

Fortunately, this is potentially easy using the system described above, and requires no moving parts. Referring to the flowchart of FIG. 6, as the microdisplay 36 goes through its refresh cycles, the method works by the computer 50 executing the following steps:

60. Calculate a low (or standard) resolution image 41 for the entire display area 40.

61. Display the image 41 on the microdisplay 36 by writing the low (or standard) resolution image 41 onto the pixels for the entire display area 40.

62. Determine the user's area of interest (AOI) 42 in the image by finding the gaze point 53 using a gaze tracker 51.

63. Determine the additional area 46 around the AOI covering the range of rapid saccadic eye movements and extra area beyond that to ensure overlap between one AOI position and the next during rapid longer range eye movements.

64. Calculate a high resolution image for display inside the additional area 46.

65. Write the small, high resolution AOI image with every spot flash within the area of interest 42 and within the additional area 46 around the area of interest 42. Since the information on the pixels outside the AOI remains the same during the entire (typically 1/60th second) flash cycle, the image will have a resolution equal to the pixel resolution of the microdisplay.

66. Repeat the method from step 60.

To change the position of the AOI 42, all that one has to do is change the position of the area 46 where high resolution information is being read onto the microdisplay 36. One can do this purely in software, without any mechanical movement.

Assuming that the computer 50 can calculate and display sixty high resolution AOI inserted images per second, the lag caused by this part of the system will be a maximum of one microdisplay refresh cycle, typically about 1/60th second, between any two successive AOI positions, no matter how widely separated they are. In addition, it may be beneficial to move the AOI from position to position during less than 1/60th second refresh cycle, for example during each 1/540th field, displaying different details of a moving image as it goes along and the eye follows it. It also may be possible, with some microdisplays, to run the microdisplays at a significantly faster rate than 60 flash cycles per second, potentially leading to even less lag.

Accordingly, it is to be understood that the embodiments of the invention herein described are merely illustrative of the application of the principles of the invention. Reference herein to details of the illustrated embodiments is not intended to limit the scope of the claims, which themselves recite those features regarded as essential to the invention.

What is claimed is:

1. An enhanced resolution microdisplay system comprising:
a) a beam splitter having a first side, a second side opposite the first side, a third side, a fourth side opposite the third side, and a partially reflecting mirror oriented to reflect a portion of light entering through the first side to the third side and a portion of light entering through the fourth side to the second side;
b) a microlens array adjacent to the first side of the beam splitter;
c) output optics adjacent to the second side of the beam splitter;
d) at least one dichroic mirror having a thickness and a position adjacent to the third side of the beam splitter, the at least one dichroic mirror being selected to reflect light of a color while passing other colors;
e) a microdisplay adjacent to the fourth side of the beam splitter;
f) a beam combiner adjacent to the microlens array, the beam combiner having at least two inputs and an output oriented such that light entering the at least two inputs is combined in the output and passes to the fly's eye lens; and
g) at least one light source emitting light of a color into one of the at least two inputs of the beam combiner, the color of the at least one light source being selected to be same color reflected by the at least one dichroic mirror;
the thicknesses and positions of the at least one mirror being selected such that a travel distance for light from the at least one light source emitting light in a color which is reflected by the at least one mirror causes a Talbot plane image of the light source to be focused on the microdisplay.

2. The display of claim 1 in which the output optics comprise viewing optics.

3. The display of claim 1 in which the output optics comprise a projector lens.

4. The display of claim 1, in which there are three light sources emitting light in three different colors, and there are three mirrors, at least two of the mirrors being dichroic mirrors selected to reflect color emitted by one of the three light sources.

5. The display of claim 4, in which all of the three mirrors are dichroic mirrors, each mirror being selected to reflect a color emitted by one of the three light sources.

6. The display of claim 4, in which the three mirrors are arranged such that Talbot plane images of the colors emitted by the three light sources are coincident in one plane.

7. The display of claim 6, in which the one plane is a pixel plane of the microdisplay.

8. The display of claim 4, in which the colors emitted by the three light sources are red, green and blue.

9. The display of claim 1, in which the at least one light source is a laser diode.

10. The display of claim 6, in which the laser diode has a Bragg reflector.

11. The display of claim 1, further comprising a ¼ wave retarder between the at least one mirror and the third side of the beam splitter.

12. The display of claim 1, further comprising thermal expansion blocks at edges of the fly's eye lens, the thermal expansion blocks being selected such that a distance of a light path between the microlens and the at least one mirror and the microdisplay changes with temperature.

13. The display of claim 1, in which the microdisplay is reflective.

14. A method of increasing the resolution of an image displayed to a user on a microdisplay having a display area, comprising the steps of:
a) a computer calculating a lower resolution image for an entire display area of the microdisplay;
b) the computer writing the lower resolution image onto the pixels for the entire display area of the microdisplay;
c) the computer determining an area of interest of the user in the image by finding a gaze point of the user using a gaze tracker;
d) the computer calculating a high resolution image for display at least inside the area of interest;
e) the computer writing the high resolution image calculated in step (d) to the microdisplay at least within the area of interest; and
f) repeating the method from step (a).

15. The method of claim 15, further comprising the step, between step (c) and step (d), of the computer determining an additional area around the area of interest to cover at least one of an area within a range of rapid saccadic eye movements and an area for overlap between one area of interest position and a next area of interest during rapid longer range eye movements, and in step (d) the method, the high resolution image is calculated for the additional area.
